(19) United States
(12) Patent Application Publication
(10) Pub. No.: US 2026/0150360 A1
(43) Pub. Date: May 28, 2026

(54) WAFER AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Seiya TAKEDA, Yokohama (JP); Ryoma KANEKO, Ota (JP); Jumpei TAJIMA, Mitaka (JP); Toshiki HIKOSAKA, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/252,041

(22) Filed: Jun. 27, 2025

(30) Foreign Application Priority Data
Nov. 27, 2024 (JP) 2024-206623

(51) Int. Cl. H10D 62/815; H10D 30/47; H10D 62/10; H10D 62/60

(52) U.S. Cl. CPC H10D 62/8164; H10D 30/475; H10D 30/476; H10D 62/124; H10D 62/60

(57) ABSTRACT

According to one embodiment, a wafer includes a base; and a nitride member. The nitride member includes an intermediate nitride layer including Al_{α1}Ga_{1-α1}N (0<α1≤1), a first nitride layer including Al_{z1}Ga_{1-z1}N (0<z1<α1), a second nitride layer including Al_{z2}Ga_{1-z2}N (0<z2<α1), and a third nitride layer including Al_{z3}Ga_{1-z3}N (0≤z3<z2). The intermediate nitride layer is between the base and the third nitride layer in a first direction from the base to the nitride member. The first nitride layer is between the intermediate nitride layer and the third nitride layer. The second nitride layer is between the first nitride layer and the third nitride layer. A second carbon concentration in the second nitride layer is lower than a first carbon concentration in the first nitride layer and lower than a third carbon concentration in the third nitride layer.

### CROSS-REFERENCE TO RELATED APPLICATIONS

This application is based upon and claims the benefit of priority from Japanese Patent Application No. 2024-206623, filed on Nov. 27, 2024; the entire contents of which are incorporated herein by reference.

### FIELD

Embodiments described herein relate generally to a wafer and a semiconductor device.

### BACKGROUND

For example, improved performance is desired in semiconductor devices based on wafers including nitride.

### BRIEF DESCRIPTION OF THE DRAWINGS

FIG. 1 is a schematic cross-sectional view illustrating a wafer according to a first embodiment;

FIG. 2 is a graph illustrating the wafer according to the first embodiment;

FIG. 3 is a graph illustrating the characteristics of the wafer;

FIG. 4 is a graph illustrating the characteristics of the wafer;

FIG. 5 is a schematic cross-sectional view illustrating a wafer according to the first embodiment;

FIG. 6 is a schematic cross-sectional view illustrating a wafer according to the first embodiment;

FIG. 7 is a schematic cross-sectional view illustrating a semiconductor device according to a second embodiment; and

FIG. 8 is a schematic cross-sectional view illustrating a semiconductor device according to the second embodiment.

### DETAILED DESCRIPTION

According to one embodiment, a wafer includes a base; and a nitride member. The nitride member includes an intermediate nitride layer including Al_{α1}Ga_{1-α1}N (0<α1≤1), a first nitride layer including Al_{z1}Ga_{1-z1}N (0<z1<α1), a second nitride layer including Al_{z2}Ga_{1-z2}N (0<z2<α1), and a third nitride layer including Al_{z3}Ga_{1-z3}N (0≤z3<z2). The intermediate nitride layer is between the base and the third nitride layer in a first direction from the base to the nitride member. The first nitride layer is between the intermediate nitride layer and the third nitride layer. The second nitride layer is between the first nitride layer and the third nitride layer. A second carbon concentration in the second nitride layer is lower than a first carbon concentration in the first nitride layer and lower than a third carbon concentration in the third nitride layer.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

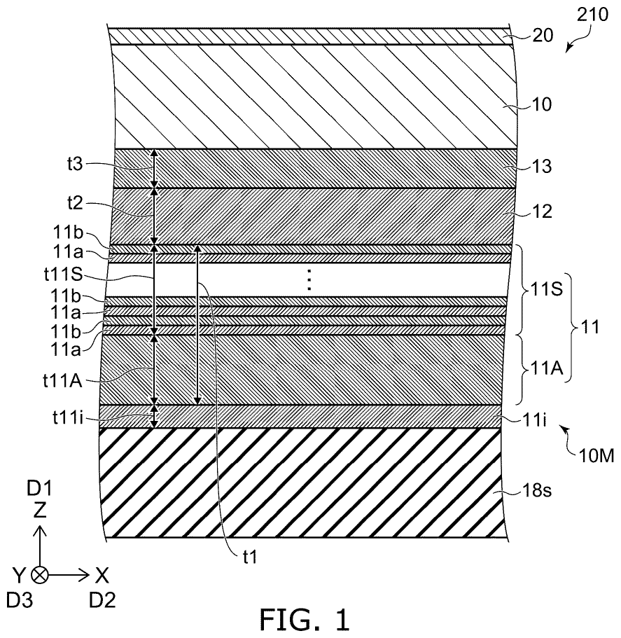

FIG. 1 is a schematic cross-sectional view illustrating a wafer according to the first embodiment.

As shown in FIG. 1, a wafer 210 according to the embodiment includes a base 18s and a nitride member 10M. As described below, the wafer 210 may further include other layers.

The nitride member 10M includes an intermediate nitride layer 11i including Al_{α1}Ga_{1-α1}N (0<α1≤1), a first nitride layer 11 including Al_{z1}Ga_{1-z1}N (0<z1<α1), a second nitride layer 12 including Al_{z2}Ga_{1-z2}N (0<z2<α1), and a third nitride layer 13 including Al_{z3}Ga_{1-z3}N (0≤z3<z2).

The intermediate nitride layer 11i is located between the base 18s and the third nitride layer 13 in a first direction D1 from the base 18s to the nitride member 10M.

The first direction D1 is defined as a Z-axis direction. One direction perpendicular to the Z-axis direction is defined as an X-axis direction. A direction perpendicular to the Z-axis and X-axis directions is defined as a Y-axis direction. The base 18s is the X-Y plane. The nitride member 10M is along the X-Y plane.

The first nitride layer 11 is located between the intermediate nitride layer 11i and the third nitride layer 13. The second nitride layer 12 is located between the first nitride layer 11 and the third nitride layer 13.

For example, the composition ratio α1 may be not less than 0.9 and not more than 1. The intermediate nitride layer 11i may be, for example, an AlN layer. As described later, the composition ratio z1 may vary within the first nitride layer 11. The composition ratio z2 may be, for example, not less than 0.1 and not more than 0.5. The second nitride layer 12 may be, for example, an AlGaN layer. The composition ratio z3 may be, for example, not less than 0 and less than 0.1. The third nitride layer 13 may be, for example, a GaN layer.

In the embodiment, a second carbon concentration C2 in the second nitride layer 12 is lower than a first carbon concentration C1 in the first nitride layer 11 and is lower than a third carbon concentration C3 in the third nitride layer 13. The third nitride layer 13 is, for example, a GaN layer including carbon with a high concentration. The second nitride layer 12 is an AlGaN layer with a low carbon concentration.

It has been found that a high breakdown voltage can be obtained with the carbon concentration profile described above.

Below, three samples with different second carbon concentrations C2 will be described.

In the first sample SP1, the second carbon concentration C2 is lower than the first carbon concentration C1 and lower than the third carbon concentration C3. The first sample SP1 corresponds to the configuration of the embodiment.

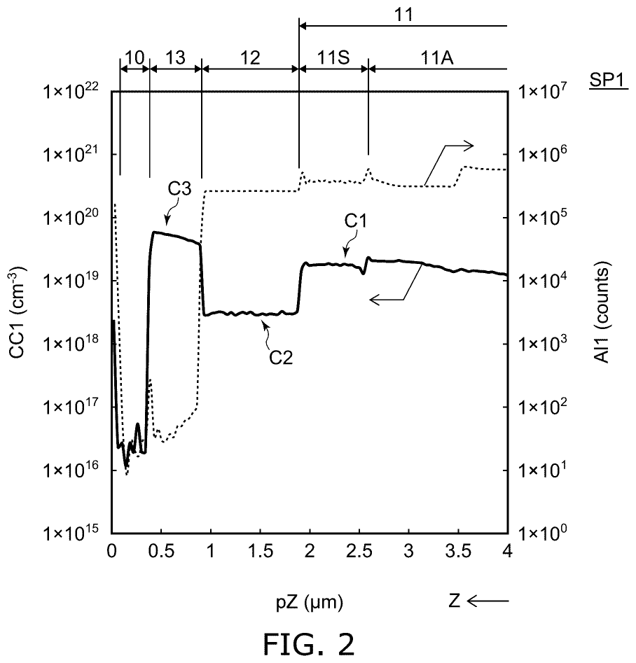

FIG. 2 is a graph illustrating a wafer according to the first embodiment.

FIG. 2 illustrates the composition and impurity profiles in the wafer 210. FIG. 2 shows the results of SIMS (Secondary Ion Mass Spectrometry) analysis of the first sample SP1. In FIG. 2, the horizontal axis is the position pZ in the Z-axis direction. The left vertical axis in FIG. 2 is the carbon concentration CC1. The right vertical axis in FIG. 2 is the Al count number Al1. In FIG. 2, the regions of the first nitride layer 11, the second nitride layer 12, and the third nitride layer 13 are shown.

As shown in FIG. 2, in the first sample SP1, the second carbon concentration C2 in the second nitride layer 12 is lower than the first carbon concentration C1 in the first nitride layer 11. The second carbon concentration C2 is lower than the third carbon concentration C3 in the third nitride layer 13.

In a second sample SP2 corresponding to a first reference example, the second carbon concentration C2 is lower than the third carbon concentration C3, but is substantially the same as the first carbon concentration C1. In a third sample SP3 corresponding to a second reference example, the second carbon concentration C2 is substantially the same as the third carbon concentration C3 and higher than the first carbon concentration C1.

The breakdown voltage of the second sample SP2 is 1.13 times the breakdown voltage of the third sample SP3. The breakdown voltage of the first sample SP1 is 1.15 times the breakdown voltage of the third sample SP3. Thus, it has been found that a high breakdown voltage can be obtained by making the second carbon concentration C2 lower than the first carbon concentration C1 and lower than the third carbon concentration C3.

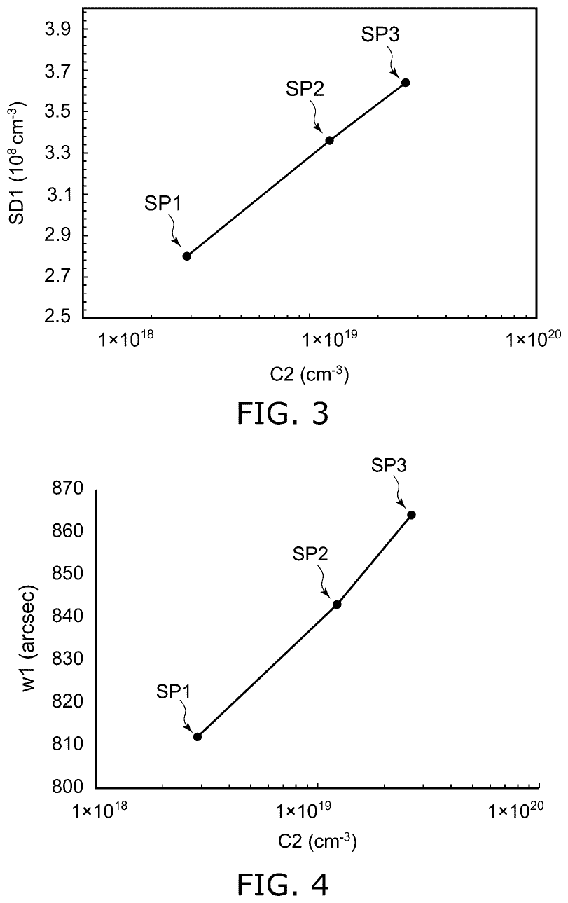

FIG. 3 is a graph illustrating the characteristics of the wafer.

The horizontal axis of FIG. 3 is the second carbon concentration C2. The vertical axis of FIG. 3 is the screw dislocation density SD1. FIG. 3 shows the evaluation results of the first sample SP1, the second sample SP2, and the third sample SP3. As shown in FIG. 3, when the second carbon concentration C2 is lower, the screw dislocation density SD1 decreases. A low screw dislocation density SD1 is obtained in the first sample SP1.

FIG. 4 is a graph illustrating the characteristics of the wafer.

The horizontal axis of FIG. 4 is the second carbon concentration C2. The vertical axis of FIG. 4 is the half-width w1 of the peak corresponding to the (002) plane of GaN in X-ray diffraction. A small half-width w1 corresponds to small crystal fluctuation and good crystallinity. FIG. 4 shows the evaluation results of the first sample SP1, the second sample SP2, and the third sample SP3. As shown in FIG. 4, when the second carbon concentration C2 is low, the half-width w1 decreases. A small half-width is obtained in the first sample SP1.

Thus, it has been found that a low second carbon concentration C2 results in a low screw dislocation density SD1. It has been found that a low second carbon concentration C2 results in a small half-width w1. It is considered than this leads to a high breakdown voltage. It is considered that high crystal quality improves the breakdown voltage.

The third nitride layer 13 is, for example, a GaN layer including carbon. It is known that a high breakdown voltage can be obtained by providing such a third nitride layer 13. This is considered to be based on the phenomena that injected carriers are trapped by the carbon-based level. On the other hand, according to the experimental results of the inventors, it has been found that a high breakdown voltage can be obtained as described above by lowering the second carbon concentration C2 in the second nitride layer 12 between the base 18s and the third nitride layer 13.

The embodiment is based on such newly found knowledge. By making the second carbon concentration C2 lower than the first carbon concentration C1 and lower than the third carbon concentration C3, a low screw dislocation density SD1 and a small half-width w1 can be obtained. It is considered that such a carbon concentration profile provides good crystallinity and a high breakdown voltage. According to the embodiment, it is possible to provide a wafer capable of improving characteristics. Furthermore, in the embodiment, it is considered that the carriers are confined in the low carbon concentration region due to the structure in which the low carbon concentration region is sandwiched between two high carbon concentration regions. It is considered that this results in a high breakdown voltage.

The above sample has the configuration illustrated in FIG. 1. The wafer 210 according to the embodiment may have the configuration illustrated in FIG. 1.

As illustrated in FIG. 1, the first nitride layer 11 may include a nitride stack 11S. The nitride stack 11S includes a plurality of first films 11a including Al_{y1}Ga_{1-y1}N (0<y1≤1) and a plurality of second films 11b including Al_{y2}Ga_{1-y2}N (0≤y2<y1). One of the plurality of first films 11a is located between one of the plurality of second films 11b and another one of the plurality of second films 11b in the first direction D1. One of the plurality of second films 11b is located between one of the plurality of first films 11a and another one of the plurality of first films 11a in the first direction D1. For example, the first films 11a and the second films 11b may be provided alternately.

The nitride stack 11S may be, for example, a superlattice layer. By providing the nitride stack 11S, for example, crystal strain is relaxed. For example, warping is suppressed. The composition ratio y1 may be, for example, not less than 0.8 and not more than 1 s. The composition ratio y2 may be, for example, not less than 0 and not more than 0.15.

The first nitride layer 11 may include an intermediate region 11A including Al, Ga, and N. The intermediate region 11A is located between the intermediate nitride layer 11i and the nitride stack 11S. In one example, an Al composition ratio in the intermediate region 11A may decrease in the direction from the intermediate nitride layer 11i to the second nitride layer 12. For example, crystal strain is relaxed. For example, warping is suppressed.

As described below, one of the nitride stack 11S and the intermediate region 11A may be omitted.

A ratio of the absolute value of the difference between the maximum and minimum carbon concentrations in the nitride stack 11S to the maximum value may be 0.1 or less. In the nitride stack 11S, the carbon concentration may be substantially constant.

A ratio of the absolute value of the difference between the maximum and minimum values of the carbon concentration in the second nitride layer 12 to the maximum value may be 0.1 or less. In the second nitride layer 12, the carbon concentration may be substantially constant.

A ratio of the absolute value of the difference between the maximum value and minimum value of the Al concentration in the second nitride layer 12 to the maximum value may be 0.1 or less. In the second nitride layer 12, the Al composition ratio may be substantially constant.

As shown in FIG. 1, a thickness of the second nitride layer 12 along the first direction D1 is defined as a second thickness t2. A thickness of the third nitride layer 13 along the first direction D1 is defined as a third thickness t3. For example, the second thickness t2 may be thicker than the third thickness t3. For example, a high breakdown voltage is more easily obtained. For example, a lower screw dislocation density SD1 is more easily obtained. For example, a smaller half-width is more easily obtained.

A thickness of the first nitride layer 11 along the first direction D1 is defined as a first thickness t1. For example, the second thickness t2 of the second nitride layer 12 may be thinner than the first thickness t1. By the first thickness t1 being thick, for example, strain can be more effectively relaxed.

In a case where the first nitride layer 11 includes the nitride stack 11S and the intermediate region 11A, the first thickness t1 may correspond to the sum of the thickness t11S of the nitride stack 11S and the thickness t11A of the intermediate region 11A.

As shown in FIG. 2, in the embodiment, the third carbon concentration C3 may be higher than the first carbon concentration C1. For example, dislocations can be effectively reduced.

The second carbon concentration C2 is preferably, for example, not less than 1×10¹⁷ cm⁻³ and not more than 1×10¹⁹ cm⁻³. A high breakdown voltage is easily obtained. For example, a low screw dislocation density SD1 is easily obtained. A small half-width w1 is easily obtained.

The third carbon concentration C3 may be, for example, more than 1×10¹⁹ cm⁻³ and not more than 1×10²⁰ cm⁻³. This makes it easy to suppress current collapse. The first carbon concentration C1 may be, for example, more than 1×10¹⁹ cm⁻³ and not more than 5×10¹⁹ cm−3. This makes it easy to suppress carrier injection.

As shown in FIG. 1, the wafer 210 may further include a first semiconductor layer 10 including Alₓ₁Ga₁₋ₓ₁N (0≤x1<1). The nitride member 10M is located between the base 18s and the first semiconductor layer 10. The composition ratio x1 may be, for example, not less than 0 and not more than 0.13. The first semiconductor layer 10 may be, for example, a GaN layer. A carbon concentration in the first semiconductor layer 10 is lower than the third carbon concentration C3 in the third nitride layer 13. The carbon concentration in the first semiconductor layer 10 is, for example, less than 1×10¹⁸ cm⁻³.

As shown in FIG. 1, the wafer 210 may further include a second semiconductor layer 20 including Alₓ₂Ga₁₋ₓ₂N (0<x2≤1, x1<x2). The first semiconductor layer 10 is located between the nitride member 10M and the second semiconductor layer 20. The composition ratio x2 may be, for example, not less than 0.15 and not more than 3.5. The second semiconductor layer 20 may be, for example, an AlGaN layer. A carbon concentration in the second semiconductor layer 20 is lower than the third carbon concentration C3 in the third nitride layer 13. The carbon concentration in the second semiconductor layer 20 is, for example, less than 1×10¹⁹ cm⁻³.

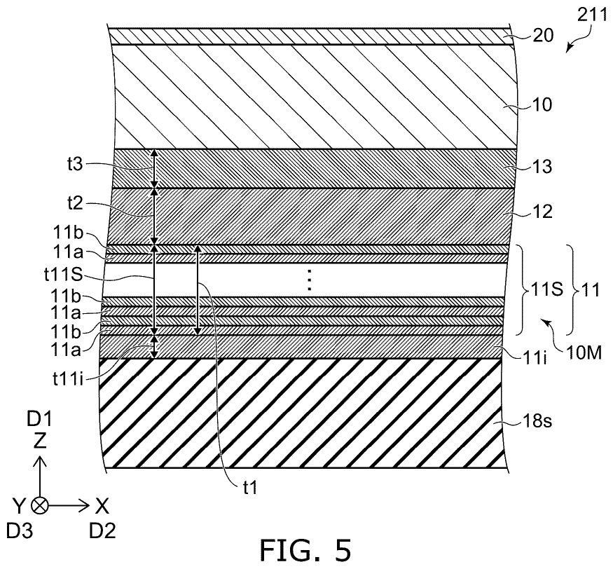

FIG. 5 is a schematic cross-sectional view illustrating a wafer according to the first embodiment.

As shown in FIG. 5, in a wafer 211 according to the embodiment, the intermediate region 11A is omitted. Except for this, the configuration of the wafer 211 may be the same as the configuration of the wafer 210. In the wafer 211, the nitride stack 11S contacts the intermediate nitride layer 11i and the second nitride layer 12.

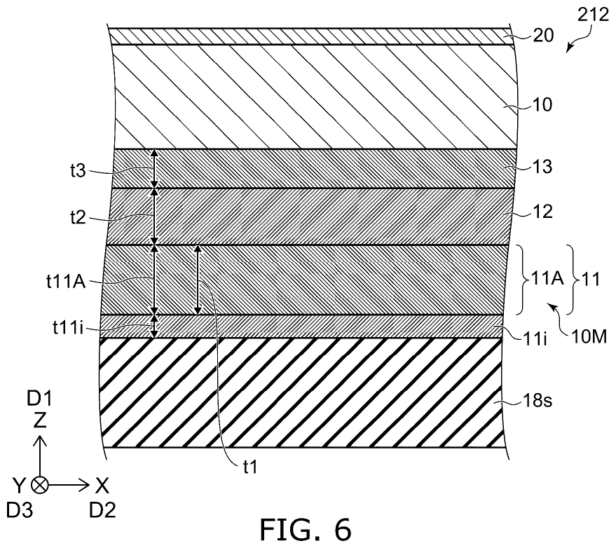

FIG. 6 is a schematic cross-sectional view illustrating a wafer according to the first embodiment.

As shown in FIG. 6, in a wafer 212 according to the embodiment, the nitride stack 11S is omitted. Except for this, the configuration of the wafer 212 may be the same as the configuration of the wafer 210.

In the wafer 212, the first nitride layer 11 includes the intermediate region 11A including Al, Ga, and N. In the wafer 212 as well, the Al composition ratio in the intermediate region 11A may decrease in the direction from the intermediate nitride layer 11i to the second nitride layer 12. In the wafer 212, the intermediate region 11A contacts the intermediate nitride layer 11i and the second nitride layer 12.

### Second Embodiment

The second embodiment relates to a semiconductor device. The semiconductor device includes the wafer 210 described in relation to the first embodiment or a variation thereof.

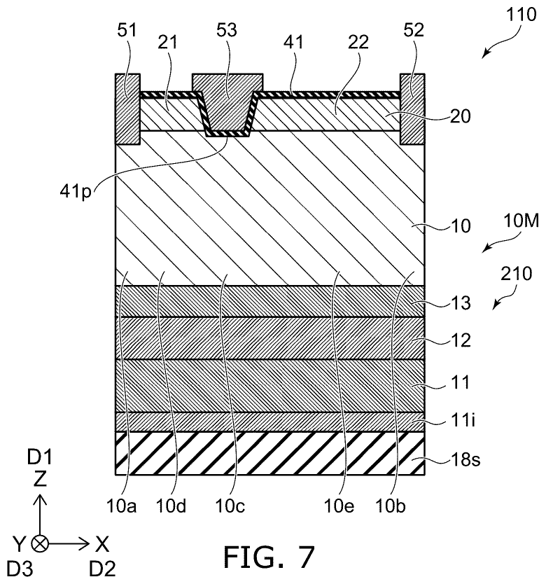

FIG. 7 is a schematic cross-sectional view illustrating a semiconductor device according to the second embodiment.

As shown in FIG. 7, a semiconductor device 110 according to the embodiment includes the wafer 210 according to the first embodiment, a first electrode 51, a second electrode 52, and a third electrode 53.

For example, in a case where the wafer 210 does not include the first semiconductor layer 10 and the second semiconductor layer 20, the semiconductor device 110 includes the first semiconductor layer 10 and the second semiconductor layer 20. The first semiconductor layer 10 includes Alₓ₁Ga₁₋ₓ₁N (0≤x1<1). The second semiconductor layer 20 includes Alₓ₂Ga₁₋ₓ₂N (0<x2≤1, x1<x2). The first semiconductor layer 10 is, for example, a GaN layer. The second semiconductor layer 20 is, for example, an AlGaN layer.

The nitride member 10M is located between the base 18s and the second semiconductor layer 20. The first semiconductor layer 10 is located between the nitride member 10M and the second semiconductor layer 20.

A second direction D2 from the first electrode 51 to the second electrode 52 crosses the first direction D1. The second direction D2 is, for example, the X-axis direction. A position of the third electrode 53 in the second direction D2 is between a position of the first electrode 51 in the second direction D2 and a position of the second electrode 52 in the second direction D2.

The second semiconductor layer 20 includes a first semiconductor portion 21 and a second semiconductor portion 22. A direction from the first semiconductor portion 21 to the second semiconductor portion 22 is along the second direction D2. The first electrode 51 is electrically connected to the first semiconductor portion 21. The second electrode 52 is electrically connected to the second semiconductor portion 22.

Current flowing between the first electrode 51 and the second electrode 52 is controlled by a potential of the third electrode 53. The potential of the third electrode 53 may be, for example, a potential based on a potential of the first electrode 51. The first electrode 51 functions, for example, as a source electrode. The second electrode 52 functions as a drain electrode. The third electrode 53 functions as a gate electrode. The semiconductor device 110 is, for example, a transistor.

The first semiconductor layer 10 includes a region facing the second semiconductor layer 20. A carrier region is formed in this region. The carrier region is, for example, a two-dimensional electron gas. The semiconductor device 110 is, for example, a HEMT (High Electron Mobility Transistor).

In the semiconductor device 110 according to the embodiment, for example, a high breakdown voltage is obtained. Good crystallinity is obtained. For example, a low on-resistance is obtained. According to the embodiment, a semiconductor device capable of improving characteristics can be provided.

As shown in FIG. 7, in this example, at least a part of the third electrode 53 may be provided between the first semiconductor portion 21 and the second semiconductor portion 22 in the second direction D2. The third electrode 53 is, for example, a recessed gate electrode. For example, a high threshold voltage is obtained. For example, normally-off operation is obtained. At least a part of the third electrode 53 may be provided between a part of the first semiconductor layer 10 and another part of the first semiconductor layer 10 in the second direction D2.

For example, the first semiconductor layer 10 includes a first partial region 10a, a second partial region 10b, a third partial region 10c, a fourth partial region 10d, and a fifth partial region 10e. A direction from the first partial region 10a to the first electrode 51 is along the first direction D1. A direction from the second partial region 10b to the second electrode 52 is along the first direction D1. A direction from the third partial region 10c to the third electrode 53 is along the first direction D1.

A fourth position in the second direction D2 of the fourth partial region 10d is between a first position in the second direction D2 of the first partial region 10a and a third position in the second direction D2 of the third partial region 10c. A fifth position in the second direction D2 of the fifth partial region 10e is between the third position in the second direction D2 of the third partial region 10c and a second position in the second direction D2 of the second partial region 10b.

A direction from the fourth partial region 10d to the first semiconductor portion 21 is along the first direction D1. A direction from the fifth partial region 10e to the second semiconductor portion 22 is along the first direction D1. In this example, a part of the third electrode 53 is between the fourth partial region 10d and the fifth partial region 10e in the second direction D2. A high threshold voltage is obtained. For example, normally-off operation is stably obtained.

As shown in FIG. 7, the semiconductor device 110 may further include a first insulating member 41. The first insulating member 41 includes a first insulating portion 41p. The first insulating portion 41p is provided between the third electrode 53 and the nitride member 10M. The first insulating portion 41p functions as, for example, a gate insulating film.

The electrodes may extend along a third direction D3. The third direction D3 crosses a plane including the first direction D1 and the second direction D2.

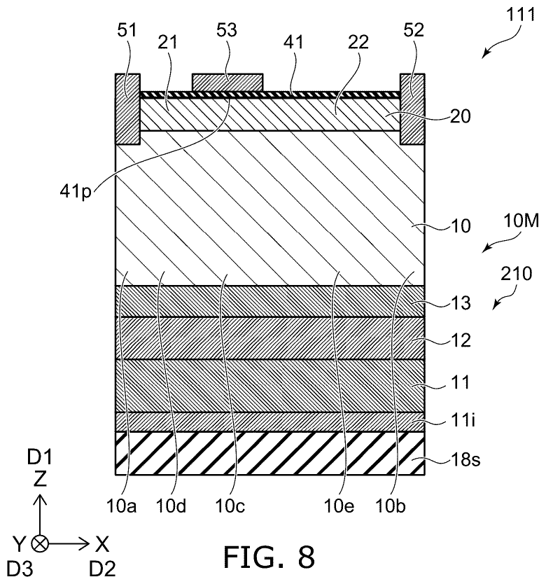

FIG. 8 is a schematic cross-sectional view illustrating a semiconductor device according to the second embodiment.

As shown in FIG. 8, a semiconductor device 111 according to the embodiment includes the wafer 210 according to the first embodiment, the first electrode 51, the second electrode 52, and the third electrode 53. In the semiconductor device 111, the third electrode 53 does not overlap the second semiconductor layer 20 in the second direction D2. Except for this, the configuration of the semiconductor device 111 may be the same as that of the semiconductor device 110.

In the semiconductor device 111, for example, normally-on operation is obtained. In the semiconductor device 111, the first insulating member 41 may be omitted. The semiconductor device 111 may be used, for example, as a high-frequency switching element.

In the embodiment, information regarding the shape of the nitride layer may be obtained, for example, by electron microscope observation. Information regarding the composition and element concentrations in the nitride layer may be obtained, for example, by EDX (Energy Dispersive X-ray Spectroscopy) or SIMS (Secondary Ion Mass Spectrometry). Information regarding the composition in the nitride layer may be obtained, for example, by reciprocal space mapping.

The embodiments may include the following Technical proposals:

### Technical Proposal 1

A wafer, comprising:
a base; and
a nitride member,
the nitride member including:
an intermediate nitride layer including Al_{α1}Ga_{1-α1}N (0<α1≤1),
a first nitride layer including Al_{z1}Ga_{1-z1}N (0<z1<α1),
a second nitride layer including Al_{z2}Ga_{1-z2}N (0<z2<α1), and
a third nitride layer including Al_{z3}Ga_{1-z3}N (0≤z3<z2),
the intermediate nitride layer being between the base and the third nitride layer in a first direction from the base to the nitride member,
the first nitride layer being between the intermediate nitride layer and the third nitride layer,
the second nitride layer being between the first nitride layer and the third nitride layer,
a second carbon concentration in the second nitride layer being lower than a first carbon concentration in the first nitride layer and lower than a third carbon concentration in the third nitride layer.

### Technical Proposal 2

The wafer according to Technical proposal 1, wherein
the first nitride layer includes a nitride stack,
the nitride stack includes
   a plurality of first films including Al_{y1}Ga_{1-y1}N (0<y1≤1), and
   a plurality of second films including Al_{y2}Ga_{1-y2}N (0≤y2<y1),
one of the plurality of first films is between one of the plurality of second films and another one of the plurality of second films in the first direction, and
the one of the plurality of second films is between the one of the plurality of first films and another one of the plurality of first films in the first direction.

### Technical Proposal 3

The wafer according to Technical proposal 2, wherein
the first nitride layer includes an intermediate region including Al, Ga, and N, and
the intermediate region is between the intermediate nitride layer and the nitride stack.

### Technical Proposal 4

The wafer according to Technical proposal 3, wherein
an Al composition ratio in the intermediate region decreases in a direction from the intermediate nitride layer to the second nitride layer.

### Technical Proposal 5

The wafer according to Technical proposal 1, wherein
the first nitride layer includes an intermediate region including Al, Ga, and N.

### Technical Proposal 6

The wafer according to Technical proposal 5, wherein
an Al composition ratio in the intermediate region decreases in a direction from the intermediate nitride layer to the second nitride layer.

### Technical Proposal 7

The wafer according to Technical proposal 2, wherein
a ratio of an absolute value of a difference between a maximum value and a minimum value of carbon concentration in the nitride stack to the maximum value is 0.1 or less.

### Technical Proposal 8

The wafer according to any one of Technical proposals 1-6, wherein
a ratio of an absolute value of a difference between a maximum value and a minimum value of carbon concentration in the second nitride layer to the maximum value is 0.1 or less.

### Technical Proposal 9

The wafer according to any one of Technical proposals 1-6, wherein
a ratio of an absolute value of a difference between a maximum value and a minimum value of an Al concentration in the second nitride layer to the maximum value is 0.1 or less.

### Technical Proposal 10

The wafer according to any one of Technical proposals 1-9, wherein
a second thickness of the second nitride layer is thicker than a third thickness of the third nitride layer.

### Technical Proposal 11

The wafer according to any one of Technical proposals 1-9, wherein
a second thickness of the second nitride layer is thinner than a first thickness of the first nitride layer.

### Technical Proposal 12

The wafer according to any one of Technical proposals 1-11, wherein
the third carbon concentration is higher than the first carbon concentration.

### Technical Proposal 13

The wafer according to any one of technical proposals 1-12, wherein
the second carbon concentration is not less than 1×10¹⁷ cm⁻³ and not more than 1×10¹⁹ cm⁻³.

### Technical Proposal 14

The wafer according to any one of technical proposals 1-13, wherein
the third carbon concentration is more than 1×10¹⁹ cm⁻³ and not more than 1×10²⁰ cm⁻³.

### Technical Proposal 15

The wafer according to any one of technical proposals 1-14, wherein
the first carbon concentration is more than 1×10¹⁹ cm⁻³ and not more than 5×10¹⁹ cm⁻³.

### Technical Proposal 16

The wafer according to any one of Technical proposals 1-15, further comprising:
a first semiconductor layer including Alₓ₁Ga₁₋ₓ₁N (0≤x1<1),
the nitride member being between the base and the first semiconductor layer.

### Technical Proposal 17

The wafer according to Technical proposal 16, further comprising:
a second semiconductor layer including Alₓ₂Ga₁₋ₓ₂N (0<x2≤1, x1<x2),
the first semiconductor layer being between the nitride member and the second semiconductor layer.

### Technical Proposal 18

A semiconductor device, comprising:
the wafer according to any one of technical proposals 1-15;
a first electrode;
a second electrode;
a third electrode;
a first semiconductor layer including Alₓ₁Ga₁₋ₓ₁N (0≤x1<1); and
a second semiconductor layer including Alₓ₂Ga₁₋ₓ₂N (0<x2≤1, x1<x2),
the nitride member being between the base and the second semiconductor layer,
the first semiconductor layer being between the nitride member and the second semiconductor layer,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion,
the second electrode being electrically connected to the second semiconductor portion.

### Technical Proposal 19

The semiconductor device according to Technical proposal 18, wherein
at least a part of the third electrode is provided between the first semiconductor portion and the second semiconductor portion in the second direction.

### Technical Proposal 20

The semiconductor device according to Technical proposal 18, wherein
at least a part of the third electrode is provided between a part of the first semiconductor layer and another part of the first semiconductor layer in the second direction.

According to the embodiments, it is possible to provide a wafer and a semiconductor device with improved characteristics.

In the specification, “an electrically connected state” includes a state in which multiple conductors are in physical contact with each other and current flows between these multiple conductors. “An electrically connected state” includes a state in which another conductor is inserted between multiple conductors and current flows between these multiple conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the wafers and semiconductor devices such as bases, nitride layers, electrodes, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all wafers and all semiconductor devices practicable by an appropriate design modification by one skilled in the art based on the wafers and semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A wafer, comprising:
a base; and
a nitride member,
the nitride member including:
an intermediate nitride layer including Al_{α1}Ga_{1-α1}N (0<α1≤1),
a first nitride layer including Al_{z1}Ga_{1-z1}N (0<z1<α1),
a second nitride layer including Al_{z2}Ga_{1-z2}N (0<z2<α1), and
a third nitride layer including Al_{z3}Ga_{1-z3}N (0≤z3<z2),
the intermediate nitride layer being between the base and the third nitride layer in a first direction from the base to the nitride member,
the first nitride layer being between the intermediate nitride layer and the third nitride layer,
the second nitride layer being between the first nitride layer and the third nitride layer,
a second carbon concentration in the second nitride layer being lower than a first carbon concentration in the first nitride layer and lower than a third carbon concentration in the third nitride layer.

2. The wafer according to claim 1, wherein
the first nitride layer includes a nitride stack,
the nitride stack includes
a plurality of first films including Al_{y1}Ga_{1-y1}N (0<y1≤1), and
a plurality of second films including Al_{y2}Ga_{1-y2}N (0≤y2<y1),
one of the plurality of first films is between one of the plurality of second films and another one of the plurality of second films in the first direction, and
the one of the plurality of second films is between the one of the plurality of first films and another one of the plurality of first films in the first direction.

3. The wafer according to claim 2, wherein
the first nitride layer includes an intermediate region including Al, Ga, and N, and
the intermediate region is between the intermediate nitride layer and the nitride stack.

4. The wafer according to claim 3, wherein
an Al composition ratio in the intermediate region decreases in a direction from the intermediate nitride layer to the second nitride layer.

5. The wafer according to claim 1, wherein
the first nitride layer includes an intermediate region including Al, Ga, and N.

6. The wafer according to claim 5, wherein
an Al composition ratio in the intermediate region decreases in a direction from the intermediate nitride layer to the second nitride layer.

7. The wafer according to claim 2, wherein
a ratio of an absolute value of a difference between a maximum value and a minimum value of carbon concentration in the nitride stack to the maximum value is 0.1 or less.

8. The wafer according to claim 1, wherein
a ratio of an absolute value of a difference between a maximum value and a minimum value of carbon concentration in the second nitride layer to the maximum value is 0.1 or less.

9. The wafer according to claim 1, wherein
a ratio of an absolute value of a difference between a maximum value and a minimum value of an Al concentration in the second nitride layer to the maximum value is 0.1 or less.

10. The wafer according to claim 1, wherein
a second thickness of the second nitride layer is thicker than a third thickness of the third nitride layer.

11. The wafer according to claim 1, wherein
a second thickness of the second nitride layer is thinner than a first thickness of the first nitride layer.

12. The wafer according to claim 1, wherein
the third carbon concentration is higher than the first carbon concentration.

13. The wafer according to claim 1, wherein
the second carbon concentration is not less than 1×10¹⁷ cm⁻³ and not more than 1×10¹⁹ cm⁻³.

14. The wafer according to claim 13, wherein
the third carbon concentration is more than 1×10¹⁹ cm⁻³ and not more than 1×10²⁰ cm⁻³.

15. The wafer according to claim 14, wherein
the first carbon concentration is more than 1×10¹⁹ cm⁻³ and not more than 5×10¹⁹ cm⁻³.

16. The wafer according to claim 1, further comprising:
a first semiconductor layer including Alₓ₁Ga₁₋ₓ₁N (0≤x1<1),
the nitride member being between the base and the first semiconductor layer.

17. The wafer according to claim 16, further comprising:
a second semiconductor layer including Alₓ₂Ga₁₋ₓ₂N (0<x2≤1, x1<x2),
the first semiconductor layer being between the nitride member and the second semiconductor layer.

18. A semiconductor device, comprising:
the wafer according to claim 1;
a first electrode;
a second electrode;
a third electrode;
a first semiconductor layer including Alₓ₁Ga₁₋ₓ₁N (0≤x1<1); and
a second semiconductor layer including Alₓ₂Ga₁₋ₓ₂N (0<x2≤1, x1<x2),
the nitride member being between the base and the second semiconductor layer,
the first semiconductor layer being between the nitride member and the second semiconductor layer,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion,
the second electrode being electrically connected to the second semiconductor portion.

19. The semiconductor device according to claim 18, wherein
at least a part of the third electrode is provided between the first semiconductor portion and the second semiconductor portion in the second direction.

20. The semiconductor device according to claim 18, wherein
at least a part of the third electrode is provided between a part of the first semiconductor layer and another part of the first semiconductor layer in the second direction.
